(19) United States
(12) Patent Application Publication
(10) Pub. No.: US 2012/0231241 A1
(43) Pub. Date: Sep. 13, 2012

(54) TRANSPARENT ELECTRODE SUBSTRATE, PRECURSOR TRANSPARENT ELECTRODE SUBSTRATE, AND METHOD FOR MANUFACTURING TRANSPARENT ELECTRODE SUBSTRATE

(75) Inventor: Tatsuya Fujita, Osaka (JP)

(73) Assignee: SHARP KABUSHIKI KAISHA, Osaka (JP)

(21) Appl. No.: 13/510,446

(22) PCT Filed: Aug. 27, 2010
(86) PCT No.: PCT/JP2010/064552

§ 371 Date: May 17, 2012

(30) Foreign Application Priority Data
Nov. 18, 2009 (JP) 2009-262604

(51) Int. Cl. B32B 3/10; C23C 14/34

(52) U.S. Cl. 428/203; 204/192.1

(57) ABSTRACT

In a transparent electrode substrate including a transparent electrode film composed of a crystallized ITO film in which an ITO film is crystallized by annealing, the present invention has an object of blocking movement of substances such as volatile components within a color filter layer to the transparent electrode film. The transparent electrode substrate (1) of the present invention includes a transparent substrate (2), an amorphous transparent conductive film (5) disposed on the upper side of the aforementioned transparent substrate (2), and a transparent electrode film (4) disposed on the upper side of the aforementioned amorphous transparent conductive film (5) and composed of a crystallized ITO film. Here, the transparent electrode film (4) is obtained by annealing the ITO film formed by a sputtering method or the like, and at the time of this annealing, the amorphous transparent conductive film (5) maintains the amorphous state and blocks the movement of the substances to the transparent electrode film (4) from the color filter layer (3) that is underneath it.

### TECHNICAL FIELD

The present invention relates to a transparent electrode substrate provided with a transparent electrode film, a precursor transparent electrode substrate used to manufacture a transparent electrode substrate, and a method for manufacturing a transparent electrode substrate.

### BACKGROUND ART

An ITO (Indium Tin Oxide) film has advantages such as low resistivity and high light transmittance and is therefore utilized as a transparent electrode film for the color filter substrate or the like of a liquid crystal display device. FIG. 4 is an explanatory diagram representing in model form the configuration of a conventional color filter substrate. As shown in FIG. 4, the color filter substrate 1P includes a transparent substrate 2P, a color filter layer 3P formed on the transparent substrate 2P, and a transparent electrode film 4P formed on the color filter layer 3P.

The transparent electrode film 4P is generally referred to as a common electrode as well and manufactured from the ITO film formed on the color filter layer 3P using a publicly known film formation method such as a sputtering method. This ITO film is also heated by annealing to a specified temperature or higher and is crystallized, thus forming the transparent electrode film 4P. In the crystallized ITO film, the resistivity becomes low, and the film quality becomes uniform overall compared to the ITO film prior to crystallization. Furthermore, depending on the conditions, the light transmittance also becomes higher than that of the ITO film prior to crystallization.

The transparent electrode film 4P may be formed directly on the surface of the color filter layer 3P as shown in FIG. 4 but may also be formed with another film being interposed as shown in Patent Document 1, for example.

Patent Document 1 shows a color filter substrate in which a color filter layer is formed on the surface of a transparent substrate. The color filter layer of this color filter substrate is provided with an underlying layer referred to as an ion-blocking layer on the surface thereof. A transparent electrode film composed of an ITO film or the like is formed on the upper side of this underlying layer. That is, the transparent electrode film is formed on the upper side of the color filter layer via the underlying layer.

As the material of the underlying layer shown in Patent Document 1, inorganic materials such as Al₂O₃, SiO, SiO₂, GaO₂, MgO, MgF₂, TiO₂, Ta₂O₃, ZnO, and ZnO₂ or organic materials such as epoxy, polyimide, polyamide, acrylic, and PVA resin are shown as examples. It is said in Patent Document 1 that by providing this underlying layer (ion-blocking layer), a reduction in lifetime of the liquid crystal that would otherwise occur due to contamination of ions from the color filter layer can be prevented.

### RELATED ART DOCUMENTS

### Patent Documents

Patent Document 1: Japanese Patent Application Laid-Open Publication No. 561-260224

### SUMMARY OF THE INVENTION

### Problems to be Solved by the Invention

When the ITO film formed directly on the surface of the color filter layer 3P is annealed as in the conventional color filter substrate 1P shown in FIG. 4, the crystallization of the ITO film is inhibited, so the film quality of the ITO film may become non-uniform overall, which poses a problem. The cause of the problem is as follows:

The color filter layer 3P of the color filter substrate 1P shown in FIG. 4 is composed of a plurality of color material portions 31P formed from red, green, or blue color material and a light-shielding black matrix portion 32P partitioning the respective color material portions 31P. These color material portions 31P and black matrix portion 32P are composed of organic materials including components which are volatilized at a specified temperature or higher (e.g., water and hydrocarbon). In cases where the color material portions 31P are composed of ink materials supplied by an inkjet technique, in particular, many volatile components are included. Thus, the ITO film is formed so as to directly cover the surface of the color filter layer 3P composed of such organic materials.

When such an ITO film is annealed, the color filter layer 3P or the like is also heated together with the ITO film. That is, at the time of annealing, the whole transparent substrate 2P together with the color filter layer 3P and the ITO film formed thereon (precursor transparent electrode substrate) is put in an annealing device (heating device). The temperature inside the heating device is set at 200 to 240° C., for example. When annealing is performed under such a high temperature condition, the volatile components or the like within the color filter layer 3P move toward the ITO film, and crystallization of the ITO film is inhibited by these volatile components and the like. When the crystallization is inhibited, the resistance value of the ITO film is increased, the transmittance is lowered, and the film quality becomes non-uniform.

The demand for even better performance characteristics (film quality) required for the transparent electrode film 4P, such as a low resistance value (resistivity), a high transmittance, high uniformity, surface smoothness, and others, has been growing in recent years. For the transparent electrode film 4P utilized in a color filter substrate for a large liquid crystal display device, in particular, the demand for a low resistivity and uniformity in film quality is high. In order to obtain a transparent electrode film 4P which can meet these requirements, the ITO film formed by a sputtering method or the like needs to be reliably crystallized by annealing.

For example, it is conceivable to interpose the conventional underlying layer disclosed in Patent Document 1 between the color filter layer 3P and the ITO film shown in FIG. 4. However, the underlying layer composed of an inorganic material such as Al₂O₃ and SiO or organic material such as epoxy resin shown in Patent Document 1 is non-conductive. Therefore, it cannot function as a part of the transparent electrode film. That is, the thickness of the color filter substrate is increased by the addition of this underlying layer.

Furthermore, although the underlying layer composed of ZnO or ZnO₂ disclosed in Patent Document 1 has conductivity, if this is formed by a sputtering method or like method, crystallization occurs partially inside this film (underlying layer), so the film quality becomes non-uniform. If the ITO film is annealed with the underlying layer having such a non-uniform film quality being interposed between the ITO film and the color filter layer 3P shown in FIG. 4, crystallization of the ITO film cannot be performed successfully. The reason for this is that minute holes are produced at the crystal grain boundaries or the like in the underlying layer composed of ZnO or ZnO₂, so this underlying layer ends up allowing substances generated from the color filter layer 3P or the like during the annealing to be diffused into and to pass through to the side of the ITO film from the aforementioned holes. When the substances that pass through during the annealing are mixed into the ITO film, air bubbles or the like are generated within the ITO film, so various defects occur such as the resistivity of the transparent electrode film 4P becoming non-uniform, thus posing a problem.

An object of the present invention is to provide a transparent electrode substrate that includes a transparent electrode film composed of a crystallized ITO film in which an ITO film is crystallized by annealing.

Another object of the present invention is to provide a precursor transparent electrode substrate which includes an ITO film that can be crystallized by annealing and can therefore become a transparent electrode film.

Another object of the present invention is to provide a method for manufacturing a transparent electrode substrate that includes a transparent electrode film composed of a crystallized ITO film in which an ITO film is crystallized by annealing.

### Means for Solving the Problems

A transparent electrode substrate according to the present invention is as follows:

1. A transparent electrode substrate including a transparent substrate, an amorphous transparent conductive film disposed on an upper side of the transparent substrate, and a transparent electrode film disposed on an upper side of the amorphous transparent conductive film and composed of a crystallized ITO film.

2. The transparent electrode substrate according to 1 above, wherein a color filter layer is present underneath the amorphous transparent conductive film.

3. The transparent electrode substrate according to 2 above, wherein the color filter layer includes ink materials supplied by an inkjet method.

4. The transparent electrode substrate according to any one of 1 to 3 above, wherein the amorphous transparent conductive film is an IZO film.

5. The transparent electrode substrate according to 4 above, wherein the IZO film is formed by a sputtering method.

6. The transparent electrode substrate according to 4 or 5 above, wherein the thickness of the IZO film is 300 to 500 angstroms.

A precursor transparent electrode substrate according to the present invention is as follows:

7. A precursor transparent electrode substrate including a transparent substrate, an amorphous transparent conductive film disposed on an upper side of the transparent substrate, and an ITO film disposed on an upper side of the amorphous transparent conductive film, with the ITO film becoming a crystallized ITO film by annealing.

8. The precursor transparent electrode substrate according to 7 above, wherein a color filter layer is present underneath the amorphous transparent conductive film.

9. The precursor transparent electrode substrate according to 8 above, wherein the color filter layer includes ink materials supplied by an inkjet method.

10. The precursor transparent electrode substrate according to any one of 7 to 9 above, wherein the amorphous transparent conductive film is an IZO film.

11. The precursor transparent electrode substrate according to 10 above, wherein the IZO film is formed by a sputtering method.

12. The precursor transparent electrode substrate according to 10 or 11 above, wherein the thickness of the IZO film is 300 to 500 angstroms.

A method for manufacturing a transparent electrode substrate according to the present invention is as follows:

13. A method for manufacturing a transparent electrode substrate including: an amorphous transparent conductive film formation step of forming an amorphous transparent conductive film by a sputtering method on an upper side of a color filter layer formed on a transparent substrate; an ITO film formation step of forming an ITO film by a sputtering method on an upper side of the amorphous transparent conductive film to obtain a precursor transparent electrode substrate; and an annealing step of annealing the ITO film of the precursor transparent electrode substrate to cause crystallization of the ITO film, thus obtaining a transparent electrode substrate.

### Effects of the Invention

In the transparent electrode substrate of the present invention, a crystallized ITO film in which an ITO film is crystallized by annealing can be utilized as the transparent electrode film.

When the precursor transparent electrode substrate of the present invention is annealed, the ITO film becomes a crystallized ITO film. Thus, the precursor transparent electrode substrate becomes a transparent electrode substrate equipped with a transparent electrode film made of the crystallized ITO film.

With the method for manufacturing a transparent electrode substrate of the present invention, it is possible to manufacture a transparent electrode substrate which uses a crystallized ITO film formed by crystallizing an ITO film by annealing as the transparent electrode film.

### BRIEF DESCRIPTION OF THE DRAWINGS

FIG. 1 is an explanatory diagram schematically showing the configuration of a transparent electrode substrate according to one embodiment.

FIG. 2 is an explanatory diagram showing the procedure of a method for manufacturing the transparent electrode substrate according to one embodiment.

FIG. 3 is an explanatory diagram showing the relationship between the resistance value of a laminated electrode film composed of an IZO film and a crystallized ITO film and the thickness of the IZO film.

FIG. 4 is an explanatory diagram schematically showing the configuration of a conventional color filter substrate.

### DETAILED DESCRIPTION OF EMBODIMENTS

Embodiments of a transparent electrode substrate, a precursor transparent electrode substrate, and a method for manufacturing a transparent electrode substrate according to the present invention will be described below with reference to figures. However, the present invention is not limited to the embodiments described as examples of the present specification.

Transparent Electrode Substrate

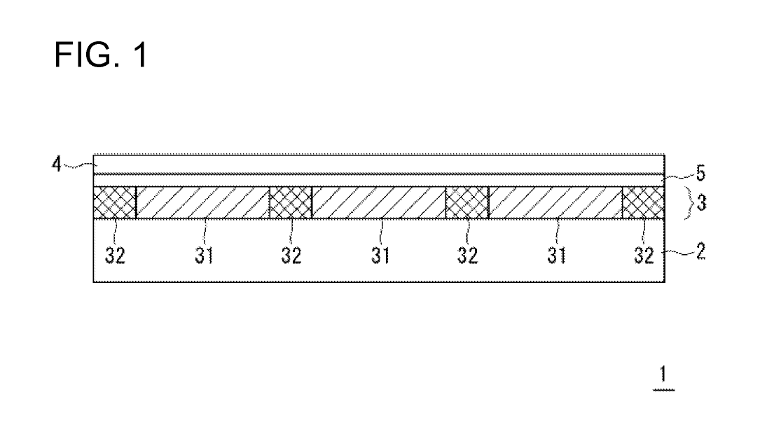

FIG. 1 is an explanatory diagram schematically showing the configuration of a transparent electrode substrate according to one embodiment. The transparent electrode substrate 1 shown in FIG. 1 is a color filter substrate 1 utilized in a liquid crystal display device. The color filter substrate 1 is disposed inside the liquid crystal display device so as to face a thin-film transistor (hereinafter referred to as TFT) substrate (not illustrated). The TFT substrate is such that a plurality of TFTs as switching elements and a plurality of pixel electrodes are formed in a matrix on a transparent glass substrate. A liquid crystal layer is sandwiched between these substrates.

The color filter substrate 1 includes a transparent substrate 2, a color filter layer 3, a transparent electrode film 4, and an amorphous transparent conductive film 5 as shown in FIG. 1.

The transparent substrate 2 is formed of a plate member made of transparent glass. Besides glass, acrylic resin or other such transparent plastic or the like can be used as examples of the material configuring the transparent substrate 2. Various parameters of the transparent substrate 2, such as the thickness, size, shape, and light transmittance, are appropriately selected in accordance with the intended use or the like of the transparent electrode substrate 1. Note that the surface of the transparent substrate 2 is preferably flat because of ease of forming another layer thereon and for other reasons.

The color filter layer 3 is composed of a plurality of light-transmissive color material portions 31 and a light-shielding black matrix portion 32 partitioning the individual color material portions 31.

The color material portions 31 are composed of a film in which a resin material is colored with a red, green, or blue dye, a film in which red, green, or blue pigment is dispersed into a resin material, a multiple interference film utilizing an inorganic material, or the like. The color material portions 31 are disposed and formed on the surface of the transparent substrate 2 using an inkjet-type supply device. The raw materials of the color material portions 31 are dispersed and dissolved in a solvent such as an organic solvent to produce a raw material solution, and this raw material solution is supplied and disposed on the transparent substrate 2 by the aforementioned supply device. The raw material solution on the transparent substrate 2 is subsequently heated by a baking treatment to form film-form color material portions 31.

Specific examples of the pigments that can be used in the color material portions are: titanium oxide, barium sulfate, calcium carbonate, zinc oxide, lead sulfate, yellow lead, zinc chrome, rouge (red iron oxide (III)), cadmium red, ultramarine, iron blue, chromic oxide green, cobalt green, amber, black titanium oxide, synthetic iron black, carbon black, and the like.

Examples of the dispersants that can be used in the color material portions are: polyoxyethylene alkyl ethers such as polyoxyethylene lauryl ether, polyoxyethylene stearyl ether, and polyoxyethylene oleyl ether; polyoxyethylene alkyl phenyl ethers such as polyoxyethylene octyl phenyl ether and polyoxyethylene nonyl phenyl ether; polyethylene glycol diesters such as polyethylene glycol dilaurate and polyethylene glycol distearate; sorbitan fatty acid esters; fatty acid modified polyesters; tertiary amine modified polyurethanes; and the like.

Examples of the solvent that can be used in the color material portions are: glycol ethers such as ethylene glycol monohexyl ether and diethylene glycol monomethyl ether; glycol ether esters such as ethylene glycol monobutyl ether acetate and diethylene glycol monomethyl ether acetate; aliphatic or aromatic esters such as ethyl acetate and propyl benzoate; dicarboxylic acid diesters such as diethyl carbonate; alkoxy carboxylic acid esters such as 3-methoxy methyl propionate; ketocarboxylic acid esters such as ethyl acetoacetate; alcohols or phenols such as ethanol, isopropanol, and phenol; aliphatic or aromatic ethers such as diethyl ether and anisole; alcohol alkoxylates such as 2-ethoxyethanol and 1-methoxy-2-propanol; glycol oligomers such as diethylene glycol and tripropylene glycol; alkoxy alcohol esters such as 2-ethoxyethyl acetate; ketones such as acetone and methyl isobutyl ketone; and the like.

The black matrix portion 32 is made by dispersing a black pigment, such as black titanium oxide or the like, in a resin material. Like the color material portions 31, the black matrix portion 32 is made by disposing, on the surface of the transparent substrate 2 using an inkjet-type supply device, a raw material solution obtained by dispersing and dissolving raw materials in a solvent such as an organic solvent. Note that the formation of the black matrix portion 32 is ordinarily performed prior to the formation of the color material portions 31. The color material portions 31 of the respective colors are formed on the transparent substrate 2 on which the black matrix portion 32 is formed. The affinity of the black matrix portion 32 to the raw material solution of the color material portions 31 (ink repellency) and the affinity of the transparent substrate 2 to the raw material solution of the color material portions 31 (ink affinity) may also be adjusted as appropriate by subjecting the respective surfaces of the black matrix portion 32 and transparent substrate 2 to a plasma treatment before the color material portions 31 are formed.

As the dispersants and solvent used in the black matrix portion 32, the ones used for the aforementioned color material portions, for example, can be utilized.

The thickness of the color filter layer 3 is set so as to be substantially constant. In the present embodiment, the thickness of the color material portions 31 and the thickness of the black matrix portion 32 are set so as to be substantially the same. In another embodiment, a transparent protective film may be formed on the upper side of the color material portions 31 and black matrix portion 32. The thickness of the color filter layer 3 may be adjusted so as to be substantially constant by means of this protective film. The thickness of the color filter layer 3 is set at 1.5 μm to 2.0 for example.

An amorphous transparent conductive film 5 is formed so as to cover the surface of the color filter layer 3. The amorphous transparent conductive film 5 is made of a transparent conductive film capable of maintaining the amorphous state at least during an annealing step, which will be described later. Specific examples of the amorphous transparent conductive film 5 are a transparent conductive film made of IZO (Indium Zinc Oxide) (hereinafter referred to as IZO film), a transparent conductive film made of amorphous ITO (hereinafter referred to as amorphous ITO film), and the like.

An IZO film is a sintered body made of a compound oxide of indium oxide (In₂O₃) and zinc oxide (ZnO), and the raw material thereof or the like is supplied by Idemitsu Kosan Co., Ltd. under the name IZO (registered trademark). The IZO film can maintain the amorphous state during the annealing step of an ITO film, which will be described later, under the temperature condition of up to approximately 300° C.

The amorphous ITO film is obtained by using mixed gas of argon (Ar) gas and water vapor (H₂O), for instance, as the sputtering gas when the ITO film is formed by a sputtering method. A concrete method for manufacturing an amorphous ITO film is shown in Japanese Patent Application Laid-Open Publication No. 2008-179850, for example. The amorphous ITO film maintains the amorphous state during the annealing step of the ITO film, which will be described later, under the temperature condition of up to approximately 150° C. Note that if the annealing step is performed under the temperature condition of approximately 200° C., the amorphous ITO film would be crystallized.

The amorphous transparent conductive film 5 is formed on the surface of the color filter layer 3 by a publicly known film formation method, such as the sputtering method, the vapor deposition method, and the ion plating method. In the present embodiment, the amorphous transparent conductive film 5 is formed directly on the surface of the color filter layer 3.

There is no special limitation in the thickness of the amorphous transparent conductive film 5 as long as the effects of the present invention are obtained, and the thickness is selected as appropriate according to the objective. Note that if the thickness of the amorphous transparent conductive film 5 is in a range from 300 angstroms to 500 angstroms, the resistivity of the amorphous transparent conductive film 5 becomes low, which is preferable.

For the amorphous transparent conductive film 5, the IZO film is more preferable between the IZO film and the amorphous ITO film. The reason for this is that the crystallization temperature of the IZO film is higher than the crystallization temperature of the amorphous ITO film, so the IZO film can maintain the amorphous state in a more stable manner during the annealing step of the ITO film, which will be described later.

The transparent electrode film 4 is composed of a crystallized ITO film and formed on the upper-side surface of the amorphous transparent conductive film 5. The crystallized ITO film of this transparent electrode film 4 is made by annealing and crystallizing an ITO film formed on the amorphous transparent conductive film 5 by a publicly known film formation method such as the sputtering method. For the ITO film used in the transparent electrode film 4, it is possible to utilize a film similar to a transparent electrode film conventionally utilized in this type of transparent electrode substrate.

It is also possible to form the amorphous transparent conductive film 5 on the color filter layer 3 by a film formation method such as a sputtering method and then to form the ITO film continuously on the amorphous transparent conductive film 5 by the same film formation method as used for this amorphous transparent conductive film 5. Alternatively, the ITO film used in the transparent electrode film 4 and the amorphous transparent conductive film 5 may be formed by different film formation methods.

The annealing (step) of the ITO film can be performed by utilizing a publicly known annealing device (heating device). When the ITO film is crystallized by annealing and becomes a crystallized ITO film, the resistivity becomes lower than before crystallization, and it becomes easier to keep the film quality uniform.

The degree of crystallization of the crystallized ITO film is selected as appropriate depending on the resistivity (low resistivity), the uniformity in the film quality, and the like required for the transparent electrode film 4. The degree of crystallization of the crystallized ITO film can be adjusted by appropriately selecting various conditions such as the heating temperature and heating time in the annealing, the cooling temperature and cooling time following heating, the ITO film composition, and the like.

As shown in FIG. 1, the transparent electrode film 4 is disposed on the upper side of the color filter layer 3 through the amorphous transparent conductive film 5. Because of this, at the time of the annealing of the ITO film, even if some ingredients of the color filter layer 3 are volatilized and are about to move to the upper side where the ITO film is disposed, the movement of these elements is blocked by the amorphous transparent conductive film 5. Accordingly, at the time of the annealing, the ITO film can be crystallized without impurities from the color filter layer 3 or the like entering the ITO film.

The color filter substrate 1 including the transparent electrode film 4 is disposed so as to face the aforementioned TFT substrate including the pixel electrodes with the liquid crystal layer being sandwiched therebetween inside the liquid crystal device as described above. When a voltage is applied across the transparent electrode film 4 and the aforementioned pixel electrodes that face each other, the liquid crystal layer is driven. Note that the amorphous transparent conductive film 5 disposed underneath the transparent electrode film 4 has conductivity and therefore functions as part of the electrode as well. Therefore, compared to a case in which the transparent electrode film is formed via a non-conductive underlying layer, the laminate composed of the transparent electrode film 4 and the amorphous transparent conductive film 5 can be made with a small thickness.

Moreover, as a result of the amorphous transparent conductive film 5 being disposed underneath the transparent electrode film 4, movement of impurities from the color filter layer 3 or the like to the liquid crystal layer by passing through the transparent electrode film 4 is also suppressed during manufacturing processes other than the annealing.

Thus, the transparent electrode substrate 1 can utilize a crystallized ITO film having a low resistance value and uniform film quality as the transparent electrode film 4.

Even in cases where the surface of the color filter layer 3 (black matrix portion 32) of the transparent electrode substrate 1 is deteriorated by plasma processing and the surface becomes rough, an increase in the resistance value of the transparent electrode film 4 can be suppressed by disposing the amorphous transparent conductive film 5 underneath the transparent electrode film 4. It is considered that when the surface of the black matrix portion 32 or the like becomes rough and the surface area is increased, impurities to be absorbed to this surface are also increased, and impurities diffusing toward the transparent electrode film 4 are also increased. However, because the amorphous transparent conductive film 5 disposed underneath the transparent electrode film 4 blocks the diffusion of the aforementioned impurities, the increase in the resistance value of the transparent electrode film 4 can be suppressed as described above. As

In another embodiment, in addition to the transparent electrode film 4, another transparent electrode film may also be laminated.

As the transparent electrode substrate 1, a substrate other than the color filter substrate 1 may also be used. For instance, the transparent electrode substrate 1 may be the TFT substrate used in the liquid crystal display device or a touch panel or the like.

In another embodiment, the transparent electrode substrate is such that another layer other than the color filter layer may also be interposed between the transparent substrate and the amorphous transparent conductive film. Further, the amorphous transparent conductive film may also be formed directly on the transparent electrode substrate depending on the intended use of the transparent electrode substrate.

Precursor Transparent Electrode Substrate

A precursor transparent electrode substrate is a transparent electrode substrate prior to annealing processing. Specifically, in a precursor transparent electrode substrate, a portion that will correspond to the transparent electrode film is made of an ITO film formed on the amorphous transparent conductive film by a sputtering method or the like. A transparent electrode substrate is obtained by converting this ITO film in the precursor transparent electrode substrate to a crystallized ITO film by annealing.

Transparent Electrode Substrate Manufacturing Method

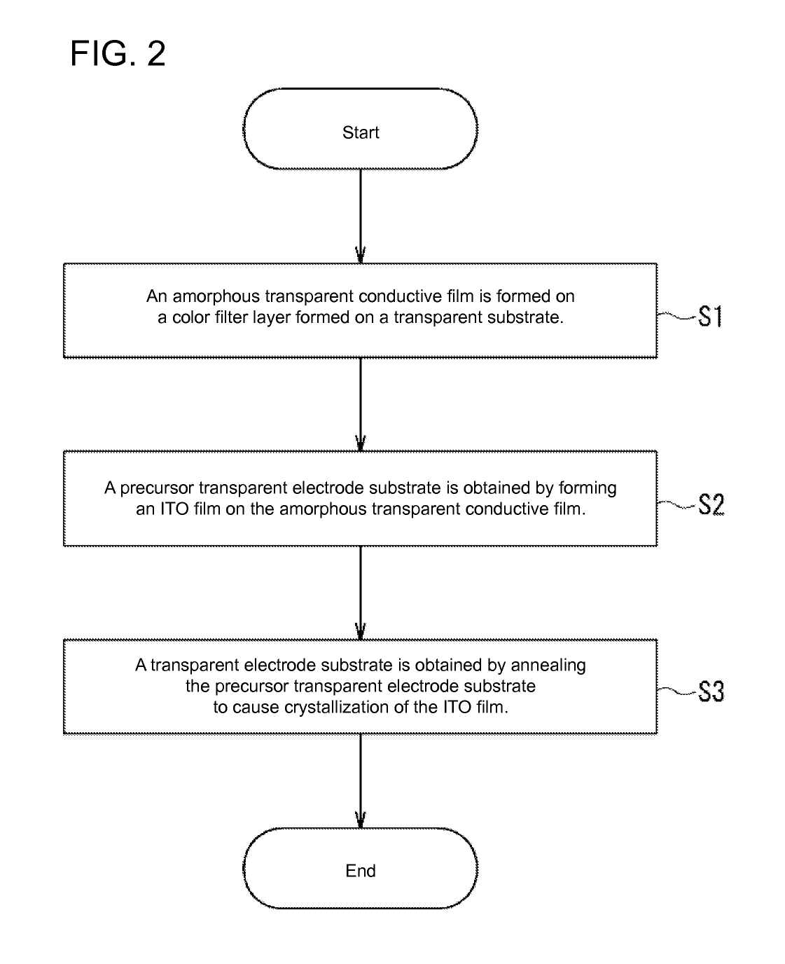

Next, a method for manufacturing a transparent electrode substrate according to one embodiment will be described with reference to FIG. 2. FIG. 2 is an explanatory diagram showing the procedure of the method for manufacturing a transparent electrode substrate according to one embodiment. The transparent electrode substrate described here is the color filter substrate 1 shown in FIG. 1.

The method for manufacturing the transparent electrode substrate 1 has an amorphous transparent conductive film formation step, an ITO film formation step, and an annealing step.

The amorphous transparent conductive film formation step is a step of forming the amorphous transparent conductive film 5 by a sputtering method on the upper side of the color filter layer 3 formed on the transparent substrate 2 (see S1 of FIG. 2). If a sputtering method is used, it is easy to obtain an amorphous transparent conductive film 5 that is in an amorphous state and that has uniform film quality.

The ITO film formation step is a step of obtaining a precursor transparent electrode substrate by forming an ITO film by a sputtering method on the upper side of the amorphous transparent conductive film 5 (see S2 of FIG. 2). Note that in the ITO film formation step, the temperature at which the ITO film is formed by the sputtering method is ordinarily lower than the temperature during the annealing step which will be described later.

The annealing step is a step of obtaining the transparent electrode substrate 1 by annealing the ITO film of the precursor transparent electrode substrate to cause crystallization of the ITO film (see S3 of FIG. 2). The annealing can be performed by using a publicly known annealing device. The entire precursor transparent electrode substrate is put in the annealing device.

As shown in FIG. 2, it is possible to manufacture the transparent electrode substrate 1 according to this procedure. The transparent electrode substrate 1 can be manufactured efficiently by using a sputtering method in forming the amorphous transparent conductive film 5 and the ITO film for the transparent electrode film 4. Note that a precursor transparent electrode substrate is obtained by performing up to the ITO film formation step of the method for manufacturing the transparent electrode substrate 1 (manufacturing steps). The method for manufacturing a transparent electrode substrate of the present invention is not limited by the above descriptions.

Measurement of Resistance Values of Transparent Electrode Film and Amorphous Transparent Conductive Film

The relationship between the resistance value of the laminated electrode film in which the transparent electrode film is laminated on the surface of the amorphous transparent conductive film (hereinafter, laminated electrode film) and the thickness of the amorphous transparent conductive film was measured by experiments. The experiments were conducted as follows.

Preparation of Test Piece 1

A transparent substrate made of glass on the surface of which a color filter layer was formed was prepared. This color filter layer was a layer in which color material portions and a black matrix portion were respectively formed on the transparent substrate by using a photolithography technique. The thickness of the color filter layer is approximately 2.0 μm.

An IZO film as an amorphous transparent conductive film was formed by a sputtering method on the surface of the color filter layer on this transparent substrate so as to have a thickness of 300 angstroms, and an ITO film was subsequently formed by a sputtering method on the IZO film so as to have a thickness of 1100 angstroms, thus obtaining a test piece 1.

The sputtering conditions of the ITO film were as follows: the purity of the target: 99.99% or higher; the composition of the target: In₂O₃=90 mass %, SnO₂=10 mass %; the density of the target: 7.08 g/cm³ or higher (relative density with respect to a theoretical density of 7.155 g/cm³); the distance between the substrate and the target: approximately 200 mm; the applied voltage: approximately 350 V; the pressure: 0.4 Pa; the temperature: 150° C.; the sputtering gas: mixed gas of Ar/O₂; flow ratio: Ar:O₂=100:1 to 3.

The sputtering conditions of the IZO film were as follows: the purity of the target: 99.99% or higher; the composition of the target: In₂O₃=90 mass %, ZnO=10 mass %; the distance between the substrate and the target: approximately 200 mm; the applied voltage: approximately 350 V; the pressure: 0.4 Pa; the temperature: 150° C.; the sputtering gas: Ar only.

Annealing of Test Piece 1

Next, the test piece 1 was annealed to crystallize the ITO film. The annealing was performed in the atmosphere under the conditions of a heating temperature of 200° C. and a heating time of 60 minutes. The test piece 1 following heating was left “as is” and cooled until it reached room temperature.

Measurement of Resistance Value of Test Piece 1

The resistance value of the laminated electrode film of the test piece 1 (sheet resistance) (Ω/□) was measured using a four-terminal four-probe-type resistivity meter (Loresta GP, made by Mitsubishi Chemical Corporation). The measurement method was complaint with JIS K7194. The sheet resistance of the laminated electrode film of the test piece 1 was 15.3 Ω/□.

Preparation of Test Pieces 2 to 5

Test pieces 2 to 5 were prepared using a manufacturing method similar to that used for the aforementioned test piece 1. The respective thicknesses of the laminated electrode films were adjusted to yield the same total thickness of 1400 angstroms among the test pieces 2 to 5. The thickness of the IZO film of the test piece 2 was set to 500 angstroms, the thickness of the IZO film of the test piece 3 was set to 100 angstroms, and the thickness of the IZO film of the test piece 4 was set to 700 angstroms. For the test piece 5, the IZO film was not formed, and only the ITO film was formed.

Annealing of Test Pieces 2 to 5

Each of the test pieces 2 to 5 was annealed to crystallize the ITO film of the laminated electrode film under the same conditions as in the aforementioned test piece 1.

Measurement of Resistance Values of Test Pieces 2 to 5

The resistance values of the laminated electrode films of the respective test pieces 2 to 5 were measured using the same measurement method as that used for the aforementioned test piece 1. The measurement results were as follows:

Sheet resistance of the laminated electrode film of test piece 2: 15.3 Ω/□

Sheet resistance of the laminated electrode film of test piece 3: 18.0 Ω/□

Sheet resistance of the laminated electrode film of test piece 4: 18.0 Ω/□

Sheet resistance of the laminated electrode film (crystallized ITO film only) of test piece 5: 20.0 Ω/□

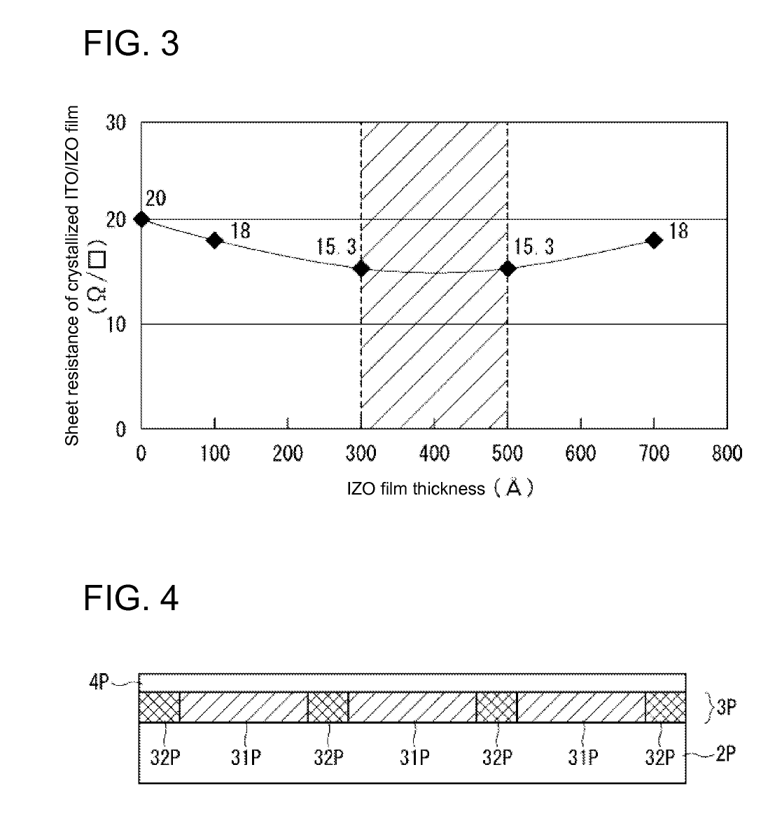

The measurement results of the resistance values (sheet resistance values) of the respective test pieces were plotted in FIG. 3. FIG. 3 is an explanatory diagram showing the relationship between the thickness of the IZO film and the resistance value of the laminated electrode film composed of the IZO film and the crystallized ITO film. In FIG. 3, the vertical axis represents the sheet resistance value (Ω/□) of the laminated electrode film composed of the crystallized ITO film and the IZO film, while the horizontal axis represents the thickness (in angstroms) of the IZO film as the amorphous transparent conductive film. As shown in FIG. 3, it was confirmed that when the thickness of the IZO film constituting the amorphous transparent conductive film is in a range from 300 angstroms (in the case of the test piece 1) to 500 angstroms (in the case of the test piece 2), the resistance value of the laminated electrode film becomes particularly low.

Furthermore, it was confirmed that when the IZO film constituting the amorphous transparent conductive film is thin as in the case of the test piece 3 (the thickness of the IZO film is 100 angstroms), the resistance value becomes high. This is presumably because the ability of the IZO film to block the movement of substances that inhibit the crystallization of the ITO film is reduced compared to the aforementioned IZO films in a range from 300 angstroms to 500 angstroms. Note that it was realized that the resistance value in the case of the test piece 3 was lower than the resistance value in the case of the test piece 5 which has no IZO film.

Moreover, it was confirmed that when the IZO film constituting the amorphous transparent conductive film is thick as in the case with the test piece 4 (the thickness of the IZO film is 700 angstroms), the resistance value becomes high compared to the aforementioned IZO films in a range from 300 angstroms to 500 angstroms. This is presumably because even though the ITO film is sufficiently crystallized, the ratio (thickness) of the IZO film, which has a higher resistance value than the crystallized ITO film, to the laminated electrode film was large.

1. A transparent electrode substrate comprising:
a transparent substrate;
an amorphous transparent conductive film disposed on an upper side of said transparent substrate; and
a transparent electrode film disposed on an upper side of said amorphous transparent conductive film, the transparent electrode film being made of a crystallized ITO film.

2. The transparent electrode substrate according to claim 1, wherein a color filter layer is disposed underneath the amorphous transparent conductive film.

3. The transparent electrode substrate according to claim 2, wherein the color filter layer includes ink materials supplied by an inkjet method.

4. The transparent electrode substrate according to any one of claim 1, wherein the amorphous transparent conductive film is an IZO film.

5. The transparent electrode substrate according to claim 4, wherein the IZO film is formed by a sputtering method.

6. The transparent electrode substrate according to claim 4, wherein the thickness of the IZO film is 300 to 500 angstroms.

7. A precursor transparent electrode substrate comprising:
a transparent substrate;
an amorphous transparent conductive film disposed on an upper side of said transparent substrate; and
an ITO film disposed on an upper side of said amorphous transparent conductive film, said ITO film being to be crystallized to become a crystallized ITO film by annealing.

8. The precursor transparent electrode substrate according to claim 7, wherein a color filter layer is disposed underneath the amorphous transparent conductive film.

9. The precursor transparent electrode substrate according to claim 8, wherein the color filter layer includes ink materials supplied by an inkjet method.

10. The precursor transparent electrode substrate according to any claim 7, wherein the amorphous transparent conductive film is an IZO film.

11. The precursor transparent electrode substrate according to claim 10, wherein the IZO film is formed by a sputtering method.

12. The precursor transparent electrode substrate according to claim 10, wherein the thickness of the IZO film is 300 to 500 angstroms.

13. A method for manufacturing a transparent electrode substrate comprising:
an amorphous transparent conductive film formation step of forming an amorphous transparent conductive film by a sputtering method on an upper side of a color filter layer formed on a transparent substrate;
an ITO film formation step of forming an ITO film by a sputtering method on an upper side of said amorphous transparent conductive film so as to form a precursor transparent electrode substrate; and
an annealing step of annealing said ITO film in said precursor transparent electrode substrate to crystallize said ITO film, thus obtaining a transparent electrode substrate.
